(19) United States
(12) Patent Application Publication
(10) Pub. No.: US 2024/0040855 A1
(43) Pub. Date: Feb. 1, 2024

(54) DISPLAY PANEL AND FABRICATION METHOD THEREOF

(71) Applicants: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(72) Inventor: Hui Song, Wuhan (CN)

(73) Assignees: WUHAN CHINA STAR OPTOELECTRONICS TECHNOLOGY CO., LTD., Wuhan (CN); WUHAN CHINA STAR OPTOELECTRONICS SEMICONDUCTOR DISPLAY TECHNOLOGY CO., LTD., Wuhan (CN)

(21) Appl. No.: 17/440,169

(22) PCT Filed: Jun. 9, 2021
(86) PCT No.: PCT/CN2021/099128

§ 371 Date: Sep. 16, 2021

(30) Foreign Application Priority Data
May 31, 2021 (CN) 202110597963.4

(51) Int. Cl. H10K 59/124; H10K 59/12

(52) U.S. Cl. CPC H10K 59/124; H10K 59/1201; H10K 2102/311

(57) ABSTRACT

The present application provides a display panel and a fabrication method thereof. The display panel comprises an under-screen camera area and a non-under-screen camera area that are adjacently arranged. The display panel comprises a first flexible substrate, a first buffer layer, a second flexible substrate, and a second buffer layer which are sequentially stacked. A first surface of the first flexible substrate is provided with a groove. The groove is located in the camera area under the screen. The display panel provided by the present application improves the light transmittance of the under-screen imaging area and improves imaging effects of a camera the under-screen.

### FIELD OF INVENTION

This application relates to a display technology field, and particularly to a display panel and a fabrication method thereof.

### BACKGROUND

With extended developments and advanced applications of OLED technology, the pursuit of high screen-to-body (or even full screen) displays with a better visual experience has become one of the current trends in the development of display technology. In order to reduce impact of a camera on the screen-to-body ratio and achieve a full screen, different manufacturers have developed a variety of solutions from different angles. One of the improved solutions is to install the front camera module at the back of the existing OLED display panel. That is, the way of using the camera under the screen.

At present, the OLED display panel of an under-screen camera usually includes a double-layer flexible substrate. A commonly used flexible substrate material is polyimide (PI). The PI material is usually in a light-yellow color. When the under-screen camera is set on ae display panel, the PI material is not conducive to light from the external environment entering the camera, resulting in poor imaging effects of the camera.

### SUMMARY OF DISCLOSURE

The present application provides a display panel and a fabrication method thereof, so as to solve problems of small light inputs and poor imaging effects of an under-screen camera of an existing display panel.

The present application provides a display panel comprising an under-screen camera area and a non-under-screen camera area that are adjacently arranged, wherein the display panel comprises:
a first flexible substrate, comprising a first surface and a second surface opposite to each other, wherein the first surface is provided with a groove, and the groove is located in the under-camera area;
a first buffer layer located on the first surface;
a second flexible substrate located on a side of the first buffer layer away from the first flexible substrate; and
a second buffer layer located on a side of the second flexible substrate away from the first buffer layer.

In some embodiments, the second flexible substrate comprises an opening, the opening is located on a side of the second flexible substrate away from the first buffer layer, and the groove and the opening are arranged correspondingly.

In some embodiments, the opening penetrates the second flexible substrate, and the second buffer layer is connected to the first buffer layer through the opening.

In some embodiments, a cross-sectional area of the opening along a thickness direction perpendicular to the second flexible substrate is greater than or equals to a cross-sectional area of the groove along a thickness direction perpendicular to the first flexible substrate.

In some embodiments, the first flexible substrate comprises a plurality of the grooves, and the plurality of grooves are arranged in the under-screen imaging area.

In some embodiments, the plurality of grooves are annular grooves, and the plurality of the grooves are concentrically arranged.

In some embodiments, a cross-sectional width of one of the grooves along the thickness direction of the first flexible substrate is between 10 micrometers and 20 micrometers.

In some embodiments, a distance between the adjacent grooves is between 5 micrometers and 20 micrometers.

In some embodiments, the display panel further comprises a light emitting device layer, the light emitting device layer is located on a side of the second buffer layer away from the second flexible substrate, the light emitting device layer comprises a plurality of pixels, and the plurality of pixels are distributed in the under-screen camera area and the non-under-screen camera area, wherein:
a pixel density of the under-screen camera area is smaller than a pixel density of the non-under-screen camera area.

In some embodiments, the display panel further comprises a driving circuit layer located between the light emitting device layer and the second buffer layer, the driving circuit layer is configured to control light emission of the pixel, the driving circuit layer comprises a plurality of thin film transistors, and the plurality of thin film transistors respectively correspond to the pixels, wherein:

the plurality of thin film transistors are connected to the plurality of pixels of the under-screen imaging area are located in the non-under-screen imaging area.

In some embodiments, the signal traces in the driving circuit layer are transparent wires.

In some embodiments, the display panel further comprises a blocking member, the blocking member is located on a side of the second buffer layer away from the second flexible substrate, and the blocking member is located between the under-screen camera area and the non-under-screen camera area.

In some embodiments, a material of the first flexible substrate and the second flexible substrate is a transparent polyimide material or a transparent polyester material.

In some embodiments, a material of the first buffer layer and the second buffer layer is silicon oxide.

In some embodiments, a thickness of the first flexible substrate and the second flexible substrate is between 6 micrometers and 12 micrometers.

In some embodiments, a thickness of the first buffer layer and the second buffer layer is between 100 nanometers and 600 nanometers.

In some embodiments, wherein the depth of the groove is between 1 micrometer and 3 micrometers.

In some embodiments, a depth of the opening is between 1 micrometer and 6 micrometers.

The present application further provides a fabrication method of a display panel, comprising:
providing a first flexible substrate, wherein the first flexible substrate comprises a first surface and a second surface that are opposed to each other;
forming a groove on the first surface, wherein the groove is located in an under-screen camera area of the display panel;
forming a first buffer layer on the first surface;
forming a second flexible substrate on the first buffer layer; and
forming a second buffer layer on the second flexible substrate.

In some embodiments, the step of forming a groove on the first surface comprises:
forming a barrier layer on the first flexible substrate;
forming a photoresist layer with a predetermined pattern on the barrier layer;
etching the barrier layer so that the barrier layer exposes the first flexible substrate;
removing the photoresist layer with the predetermined pattern;
etching the first flexible substrate to form the groove; and
removing the barrier layer.

An embodiment of the present application provides a display panel. The display panel comprises an under-screen camera area and a non-under-screen camera area that are adjacently arranged. The display panel comprises a first flexible substrate, a first buffer layer, a second flexible substrate, and a second buffer layer. The first flexible substrate has a first surface and a second surface disposed oppositely. The first surface of the first flexible substrate is provided with a groove. The groove is located in the camera area under the screen. The first buffer layer is located on the first surface of the first flexible substrate. The second flexible substrate is located on a side of the first buffer layer away from the first flexible substrate. The second buffer layer is located on a side of the second flexible substrate away from the first buffer layer. In this embodiment of the present application, grooves are provided in the under-screen imaging area of the first flexible substrate, which reduces the thickness of the flexible substrate in the under-screen imaging area, improves the light transmittance of the under-screen imaging area, and improves imaging effects of the camera in the under-screen imaging area.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a schematic structural diagram of a display panel provided by an embodiment of the present application.

FIG. 2 is a schematic structural diagram of a cross-section along a line A-A′ of a first embodiment of the display panel provided by an embodiment of the present application.

FIG. 3 is a schematic structural diagram of a cross-section along the line A-A′ of a second embodiment of a display panel provided by an embodiment of the present application.

FIG. 4 is a schematic structural diagram of a cross-section along the line A-A′ of a third embodiment of a display panel provided by an embodiment of the present application.

FIG. 5 is a schematic structural diagram of a cross-section along the line A-A′ of a fourth embodiment of a display panel provided by an embodiment of the present application.

FIG. 6 is a schematic structural diagram of a cross-section along the line A-A′ of a fifth embodiment of a display panel provided by an embodiment of the present application.

FIG. 7 is a partially enlarged view of the display panel in a region P of FIG. 6.

FIG. 8 is a schematic structural diagram of a first embodiment of a first flexible substrate provided by an embodiment of the present application.

FIG. 9 is a schematic structural diagram of a second embodiment of a first flexible substrate provided by an embodiment of the present application.

FIG. 10 is a flowchart of a fabrication method of a display panel provided by an embodiment of the present application.

FIG. 11 is a flowchart of forming a groove on a first surface of a first flexible substrate according to an embodiment of the present application.

FIG. 12 is a schematic structural diagram of forming a groove on the first surface of the first flexible substrate according to an embodiment of the present application.

### DETAILED DESCRIPTION

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

It should be noted that the terms “first” and “second” mentioned in this application do not represent any order, a quantity or importance, but are only used to distinguish different parts. The terms “up”, “down”, “left”, and “right” mentioned in this application are only the directions for referring to the attached drawings. Positional terms such as “one side” and “the other side” mentioned in this application are only used to distinguish different parts. Therefore, the serial number terms, direction terms, and position relationship terms used are used to explain and understand the application, but not to limit the application. In the application, unless expressly stipulated and defined otherwise, the first feature on “a side”, “upper” or “lower” of the second feature may include the direct contact between the first and second features; it may also include the first and second features. The second feature is not in direct contact but through another feature between them. Throughout the specification, the same reference numerals denote the same elements. Since the size and thickness of each component illustrated in the drawings are shown for convenience of description, the present disclosure is not necessarily limited to the illustrated size and thickness of each component.

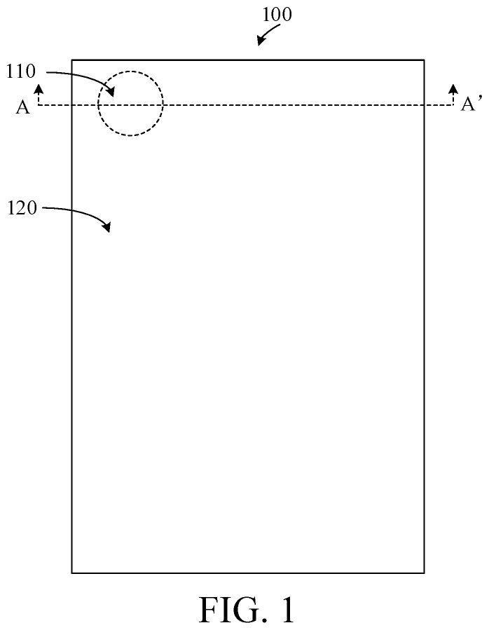

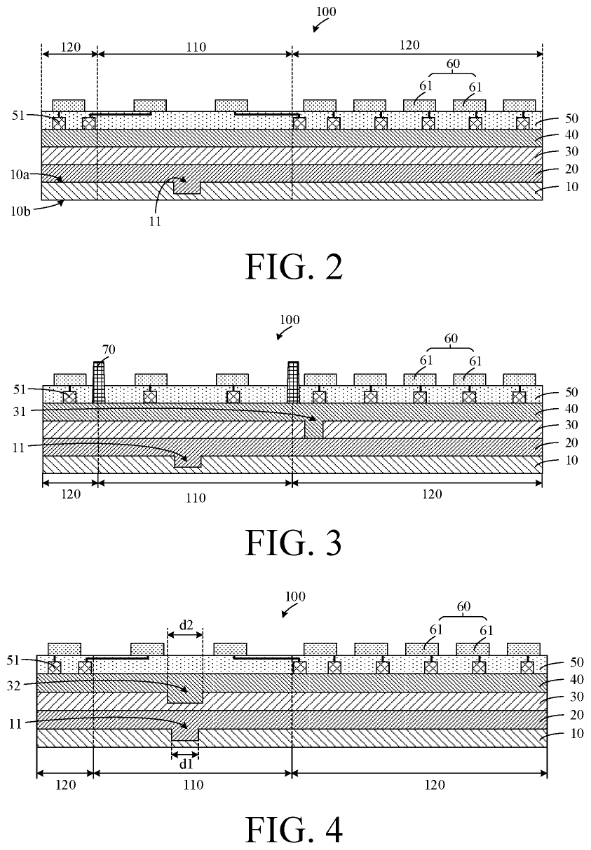

Please refer to FIGS. 1 and 2, FIG. 1 is a schematic structural diagram of a display panel provided by an embodiment of the present application, and FIG. 2 is a schematic structural diagram of a cross-section along a line A-A′ of a first embodiment of a display panel provided by an embodiment of the present application.

The display panel 100 comprises an under-screen camera area 110 and a non-under-screen camera area 120. The under-screen camera area 110 and the non-under-screen camera area 120 are arranged adjacent to each other. The under-screen camera area 110 refers to an area where a camera is placed on the display panel 100. The non-under-screen camera area 120 refers to an area of the display panel 100 excluding the under-screen camera area 110. In the present application, the camera (not shown in the figure) is located in the under-screen camera area 110, and the camera is arranged on a side of the display panel 100 away from a light-emitting surface.

The display panel 100 comprises a first flexible substrate 10, a first buffer layer 20, a second flexible substrate 30, and a second buffer layer 40. The first flexible substrate 10 comprises a first surface 10a and a second surface 10b oppositely disposed. A first surface 10a of the first flexible substrate 10 is provided with a groove 11. The groove 11 is located in the under-screen camera area 110 of the display panel 100. A camera (not shown in the figure) is provided in the under-screen imaging area 110 of the second surface 10b of the first flexible substrate 10. The first buffer layer 20 is located on the first surface 10a of the first flexible substrate 10. The first buffer layer 20 covers the groove 11, that is, a side of the first buffer layer 20 close to the first flexible substrate 10 has an extension portion (not marked in the figure), and the extension portion extends into the groove 11. The second flexible substrate 30 is located on the side of the first buffer layer 20 away from the first flexible substrate 10. The second buffer layer 40 is located on a side of the second flexible substrate 30 away from the first buffer layer 20.

It can be understood that the first surface 10a may be an upper surface of the first flexible substrate 10, and the second surface 10b may be a lower surface of the first flexible substrate 10. Of course, the first surface 10a may also be the lower surface of the first flexible substrate 10, and the second surface 10b may be the upper surface of the first flexible substrate 10. Without special instructions in this application, it is assumed that the first surface 10a is the upper surface of the first flexible substrate 10 and the second surface 10b is the lower surface of the first flexible substrate 10.

In some embodiments, thicknesses of the first flexible substrate 10 and the second flexible substrate 30 are 6 to 12 micrometers. Specifically, the thicknesses of the first flexible substrate 10 and the second flexible substrate 30 may be 6 micrometers, 8 micrometers, 9 micrometers, 10 micrometers, or 12 micrometers. The thicknesses of the first flexible substrate and the second flexible substrate 30 may be the same or different.

In some embodiments, the thicknesses of the first buffer layer 20 and the second buffer layer 40 are 100 nanometers to 600 nanometers. Specifically, the thicknesses of the first buffer layer 20 and the second buffer layer 40 may be 100 nanometers, 200 nanometers, 300 nanometers, 400 nanometers, 500 nanometers, or 600 nanometers. The thicknesses of the first buffer layer 20 and the second buffer layer 40 may be the same or different.

In some embodiments, a depth of the groove 11 is 1 micrometer to 3 micrometers. Specifically, the depth of the groove 11 may be 1 micrometer, 1.5 micrometers, 2 micrometers, 2.5 micrometers, or 3 micrometers.

In the present application, the groove 11 is provided in the under-screen imaging area 110 of the first flexible substrate 10 of the display panel 100, thereby reducing the thickness of the flexible substrate in the under-screen imaging area 110, which facilitates ambient light penetration through the display panel and increases an amount of light entering the camera under the screen, thereby improving imaging effects of the camera under the screen.

The display panel 100 further comprises a driving circuit layer 50 and a light emitting device layer 60. The driving circuit layer 50 and the light emitting device layer 60 are located on a side of the second buffer layer 40 away from the second flexible substrate 30. The driving circuit layer 50 is located between the light emitting device layer 60 and the second buffer layer 40. The light emitting device layer 60 is located on a side of the driving circuit layer 50 away from the second buffer layer 40.

The light emitting device layer 60 comprises a plurality of pixels 61. The plurality of pixels 61 are distributed in the under-screen imaging area 110 and the non-under-screen imaging area 120 of the display panel 100. A pixel density of the under-screen imaging area 110 is less than a pixel density of the non-under-screen imaging area 120.

In the present application, by making the pixel density of the under-screen camera area 110 to be less than the pixel density of the non-under-screen camera area 120, light transmittance of the under-screen camera area 110 of the display panel 100 can be further increased, and the amount of light entering the under-screen camera can be increased to further improve imaging effects of the camera under the screen.

The driving circuit layer 50 is configured to control the pixels 61 of the light emitting device layer 60 to emit light. The driving circuit layer 50 comprises a plurality of thin film transistors 51, and the thin film transistors 51 respectively correspond to the pixels 61. The thin film transistor 51 connected to the pixel 61 of the under-screen imaging area 110 is located in the non-under-screen imaging area 120.

The driving circuit layer 50 comprises a plurality of thin film transistors 51 and a plurality of signal traces. Materials of the thin film transistors 51 and the signal traces are usually a metal or a semiconductor material. Metal or semiconductor materials strongly reflect light, thereby affecting the light transmittance of the display panel 100. In the present application, the thin film transistor 51 connected to the pixel 61 of the under-screen imaging area 110 is arranged in the non-under-screen area, which reduces reflection of the metal or semiconductor material in the under-screen imaging area 110 to ambient light so that light transmittances of the under-screen imaging area 110 of the display panel 100 and the light input of the camera under the screen are increased.

In some embodiments, the signal traces in the driving circuit layer 50 can be transparent traces. The transparent traces can further reduce the reflection of ambient light from the metal or semiconductor material in the under-screen camera area 110 and increase the amount of light entering the under-screen camera.

As shown in FIG. 3, FIG. 3 is a schematic cross-sectional structure view along the line A-A′ of a second embodiment of a display panel according to an embodiment of the application.

As different from FIG. 2, the display panel 100 shown in FIG. 3 further comprises a blocking member 70, which is located on a side of the second buffer layer 40 away from the second flexible substrate 30, and the blocking member 70 is located between the under-screen camera area 110 and the non-under-screen camera area 120.

In the present application, the blocking member 70 is provided between the under-screen camera area 110 and the non-under-screen camera area 120 of the display panel 100. During the subsequent packaging process of the display panel 100, portions of the light-blocking films of the shown under-screen camera area 110 can be removed by laser, etc. to ensure that the amount of light entering the camera under the screen is increased. However, removal of portions of the light-blocking film layer will easily cause water and oxygen to easily enter the non-under-screen imaging area 120. Therefore, in the present application, a blocking member 70 is provided between the under-screen camera area 110 and the non-under-screen camera area 120 of the display panel 100, which can increase the light input of the under-screen camera while ensuring the packaging effect of the display panel 100 and avoid external water and oxygen from entering the non-under-screen camera area 120, thereby ensuring the lifespan of the display panel 100.

As shown in FIG. 3, in some embodiments, the display panel 100 is provided with a through hole 31 in the non-screen imaging area 120 of the second flexible substrate 30, so that the first buffer layer 20 and the second buffer layer 40 in the non-screen imaging area 120 are connected. The material of the first buffer layer 20 and the buffer layer is silicon oxide. The film layer formed by silicon oxide is usually a transparent and dense film layer, which can transmit light and block water and oxygen. In the present application, the through hole 31 is provided in the non-screen imaging area 120 of the second flexible substrate 30, so that the first buffer layer 20 and the second buffer layer 40 are connected, which can further prevent water vapor from passing through the gap between the first buffer layer 20 and the second flexible substrate 30 and the gap between the second flexible substrate 30 and the second buffer layer to enter the non-under-screen imaging area 120 of the display panel 100, which can improve the packaging effect of the display panel 100 and extend the lifespan of the display panel 100.

As shown in FIG. 4, FIG. 4 is a schematic structural structure of a cross-section along the line A-A′ of a third embodiment of the display panel according to an embodiment of the application.

With different from FIG. 2, the second flexible substrate 30 of the display panel 100 shown in FIG. 4 comprises an opening 32, and the opening 32 is located on a side of the second flexible substrate 30 away from the first buffer layer 20. The second buffer layer 40 covers the opening 32, that is, the side of the second buffer layer 40 close to the second flexible substrate has an extension portion (not marked in the figure), and the extension portion extends into the opening 32. Among them, the groove 11 and the opening 32 are correspondingly arranged.

In some embodiments, a depth of the opening 32 is 1 micrometer to 6 micrometers. Specifically, the depth of the opening 32 may be 1 micrometer, 2 micrometers, 3 micrometers, 4 micrometers, 5 micrometers, or 6 micrometers.

In the present application, the first buffer layer 20 is provided with the groove 11 and the second buffer layer 40 is provided with the opening 32, and the groove 11 and the opening 32 are arranged correspondingly, which can further reduce the thickness of the flexible substrate in the under-screen imaging area 110. The light transmittance of the under-screen camera area 110 is increased, and the imaging effect of the camera under the screen is improved.

As shown in FIG. 4, a cross-sectional width d2 of the opening 32 in a thickness direction perpendicular to the second flexible substrate 30 is greater than a cross-sectional width d1 of the groove 11 in a thickness direction perpendicular to the first flexible substrate 10. Therefore, under the premise that the groove 11 and the opening 32 are arranged correspondingly, a cross-sectional area of the opening 32 in the thickness direction perpendicular to the second flexible substrate 30 is larger than a cross-sectional area of the groove 11 in the thickness direction perpendicular to the first flexible substrate 10.

It can be understood that the cross-sectional width d2 of the opening 32 in the thickness direction perpendicular to the thickness of the second flexible substrate 30 can be made to be equal to the cross-sectional width d1 of the groove 11 in the thickness direction perpendicular to the first flexible substrate 10. That is, the cross-sectional area of the opening 32 in the thickness direction perpendicular to the second flexible substrate 30 is equal to the cross-sectional area of the groove 11 in the thickness direction perpendicular to the first flexible substrate 10.

In the present application, the cross-sectional area of the opening 32 in the thickness direction perpendicular to the second flexible substrate 30 is greater than or equal to the cross-sectional area of the groove 11 in the thickness direction perpendicular to the first flexible substrate 10, so that the light input of the lower camera the screen can be further increased, which helps to improve the imaging effect of the camera under the screen.

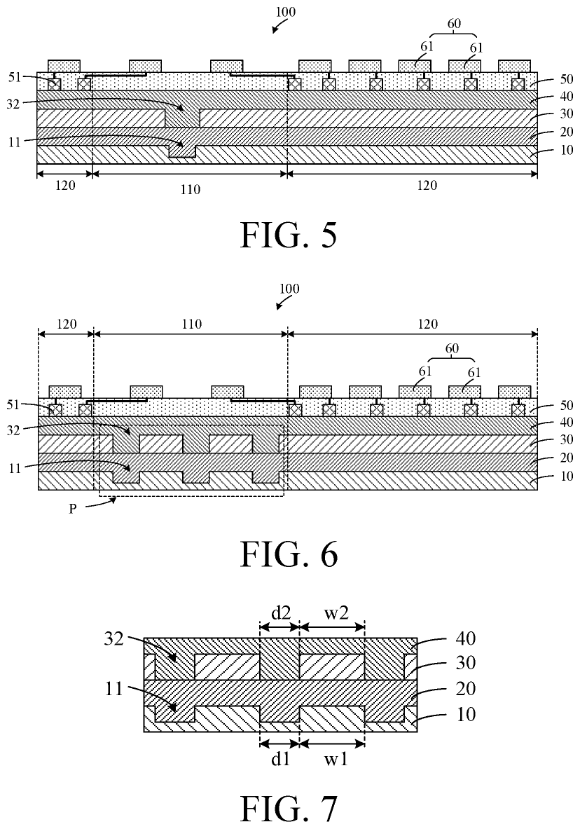

As shown in FIG. 5, FIG. 5 is a schematic structural diagram of a cross-section along the line A-A′ of a fourth embodiment of the display panel provided by an embodiment of the application.

The difference from FIG. 4 is that the opening 32 of the display panel 100 shown in FIG. 5 penetrates the second flexible substrate 30. The second buffer layer 40 is connected to the first buffer layer 20 through the opening 32.

In the present application, the opening 32 penetrates the second flexible substrate 30, which can further reduce the thickness of the flexible substrate of the under-screen imaging area 110, increase the light transmittance of the under-screen imaging area 110, and improve the imaging effect of the under-screen camera.

As shown in FIG. 6, FIG. 6 is a schematic structural diagram of a cross-section along the line A-A′ of a fifth embodiment of the display panel provided by an embodiment of the present application.

The difference from FIG. 5 is that the first flexible substrate 10 of the display panel shown in FIG. 6 comprises a plurality of grooves 11, and the plurality of grooves 11 are arranged in the under-screen imaging area 110.

In the present application, by providing a plurality of grooves 11 in the under-screen imaging area 110 of the first flexible substrate 10, the light transmittance of the under-screen imaging area 110 can be further improved, and the amount of light entering the under-screen imaging can be increased.

It can be understood that the plurality of grooves 11 disclosed in the present application refer to two or more grooves 11. In FIG. 6, three grooves 11 are provided as an example, but it is not a limitation to the embodiments of the present application.

In some embodiments, the second flexible substrate 30 of the display panel 100 comprises a plurality of openings 32, the plurality of openings 32 are arranged in the under-screen imaging area 110, and the plurality of openings 32 correspond to the plurality of grooves 11.

In the present application, a plurality of grooves 11 are provided in the under-screen imaging area 110 of the first flexible substrate 10, and a plurality of openings 32 are provided in the second flexible substrate 30, and the plurality of openings 32 are provided corresponding to the plurality of grooves 11, thereby further increasing the light transmittance of the under-screen imaging area 110 and increasing the amount of light entering the under-screen imaging camera.

Please refer to FIG. 6 and FIG. 7, FIG. 7 is a partial enlarged view of FIG. 6 in the P area.

When the first flexible substrate 10 is provided with a plurality of grooves 11 and the second flexible substrate is provided with a plurality of openings 32, the cross-sectional width d1 of the grooves 11 in the direction perpendicular to the thickness of the first flexible substrate 10 and the cross-sectional width d2 of the openings 32 in the thickness direction perpendicular to the second flexible substrate 30 are 10 micrometers to 20 micrometers. Specifically, d1 and d2 may be 10 micrometers, 12 micrometers, 14 micrometers, 15 micrometers, 16 micrometers, 18 micrometers, or 20 micrometers. The value of d2 can be greater than or equal to the value of d1. A distance w1 between adjacent grooves 11 or a distance w2 between adjacent openings 32 may be 5 micrometers to 20 micrometers. Specifically, w1 and w2 may be 5 micrometers, 8 micrometers, 10 micrometers, 12 micrometers, 15 micrometers, 18 micrometers, or 20 micrometers.

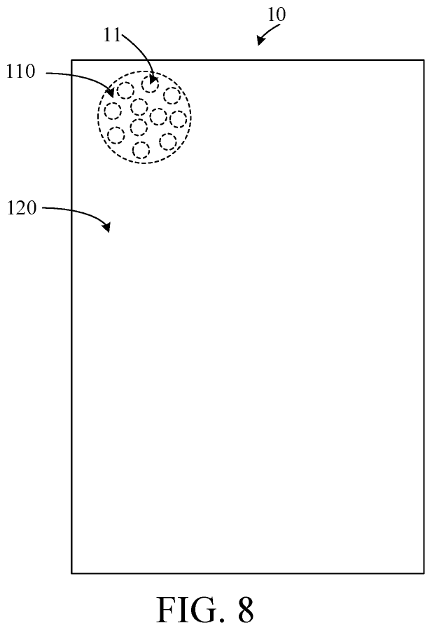

Please refer to FIGS. 6 and 8, FIG. 8 is a schematic structural diagram of a first embodiment of a first flexible substrate provided by an embodiment of the application. As shown in FIGS. 6 and 8, the first flexible substrate 10 comprises a plurality of grooves 11, and the plurality of grooves 11 are arranged in the under-screen imaging area 110. The cross-section of the grooves 11 in a thickness direction perpendicular to the first flexible substrate 10 is circular.

It can be understood that the cross-section of the grooves 11 in the direction perpendicular to the thickness of the first flexible substrate 10 may be an ellipse, triangle, quadrilateral, polygon, or other irregular shapes. The grooves 11 of the present application takes a circular cross-sectional pattern as an example, but it is not a limitation of the present application.

It can be understood that when the second flexible substrate 30 of the display panel 100 comprises a plurality of openings 32, a cross-section of the plurality of openings 32 in a direction perpendicular to the thickness direction of the second flexible substrate 30 and the cross-section of the grooves 11 in the thickness direction perpendicular to the first flexible substrate 10 are the same.

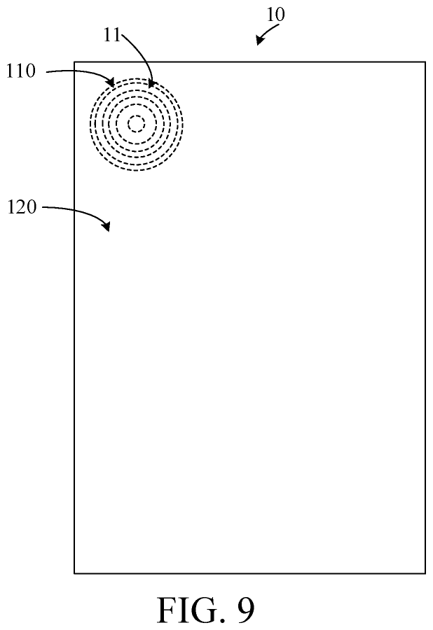

Please refer to FIG. 6 and FIG. 9, FIG. 9 is a schematic structural diagram of a second embodiment of the first flexible substrate provided by an embodiment of the application. The difference from FIG. 8 is that the grooves 11 are annular grooves 11, and the plurality of annular grooves 11 are arranged concentrically.

An embodiment of the present application provides a display panel. The display panel comprises an under-screen camera area and a non-under-screen camera area that are adjacently arranged. The display panel comprises a first flexible substrate, a first buffer layer, a second flexible substrate, and a second buffer layer. The first flexible substrate has a first surface and a second surface disposed oppositely. The first surface of the first flexible substrate is provided with a groove. The groove is located in the camera area under the screen. The first buffer layer is located on the first surface of the first flexible substrate. The second flexible substrate is located on a side of the first buffer layer away from the first flexible substrate. The second buffer layer is located on a side of the second flexible substrate away from the first buffer layer. In this embodiment of the present application, grooves are provided in the under-screen imaging area of the first flexible substrate, which reduces the thickness of the flexible substrate in the under-screen imaging area, improves the light transmittance of the under-screen imaging area, and improves imaging effects of the camera in the under-screen imaging area.

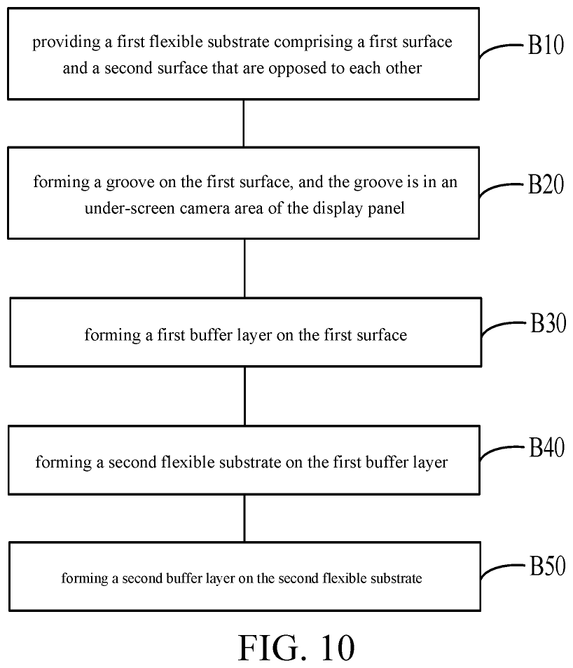

Correspondingly, embodiments of the present application also provide a fabrication method of a display panel. As shown in FIG. 10, FIG. 10 is a flowchart of a fabrication method of a display panel provided by an embodiment of the application. The fabrication method of the display panel specifically comprises the following steps:

Step B10: providing a first flexible substrate, and the first flexible substrate comprises a first surface and a second surface that are arranged opposite to each other.

A material of the first flexible substrate may be a transparent polyimide material (colorless polyimide, CPI). Specifically, the structure of polyimide molecules can be optimized by introducing fluorine-containing groups, alicyclic structures, and sulfone-containing groups into the molecular structure of polyimide (PI) to reduce intermolecular forces of the molecular structure of polyimide and reduce the formation of charge transfer complexes (CTC), thereby fabricating a colorless, transparent and high temperature resistant polyimide film (CPI).

In some embodiments, a material of the first flexible substrate may also be a transparent polyester material, such as polyethylene terephthalate (PET).

Traditional flexible substrate materials are usually in a light-yellow color. When an under-screen camera is disposed on the display panel, the traditional flexible substrate material is not conducive to light from the external environment entering the camera. The first flexible substrate of the present application uses a transparent polyimide material or a polyester material, which facilitates light from the external environment to pass through the display panel.

Step B20: forming a groove on the first surface, and the groove is located in the under-screen imaging area of the display panel.

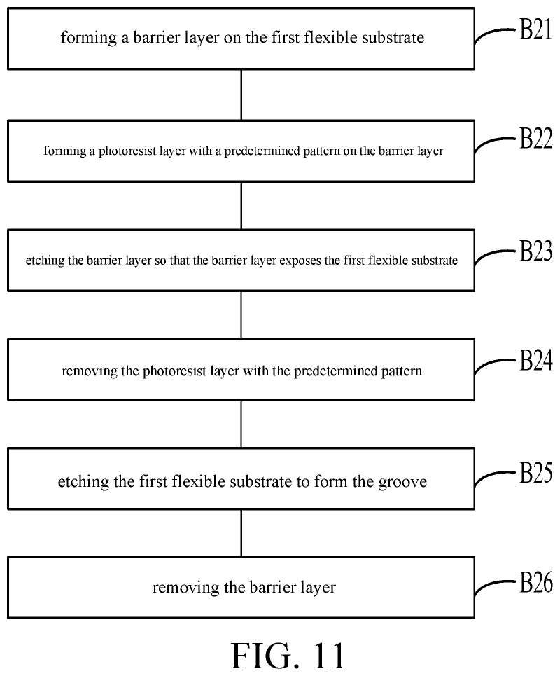

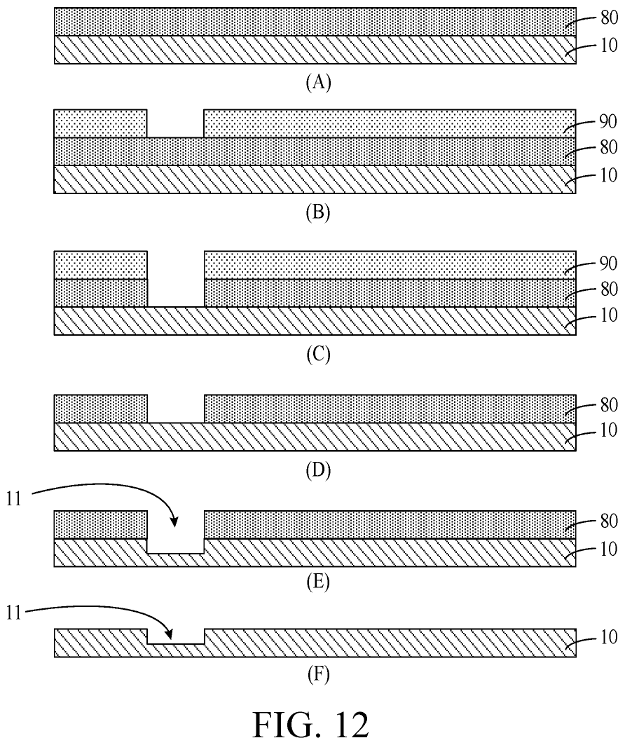

Please refer to FIG. 11 and FIG. 12, FIG. 11 is a flowchart of forming a groove on the first surface of the first flexible substrate according to an embodiment of the application. FIG. 12 is a schematic structural diagram of forming a groove on the first surface of the first flexible substrate according to an embodiment of the application.

The step of forming a groove on the first surface of the first flexible substrate comprises:

Step B21: forming a barrier layer on the first flexible substrate.

The barrier layer can be formed by processes such as electrochemical deposition or chemical vapor deposition. As shown in the structure (A) of FIG. 12, the barrier layer 80 covers the first flexible substrate 10. A material of the barrier layer 80 may be transparent conductive oxide (IZO) or indium tin oxide (ITO).

Step B22: forming a photoresist layer with a predetermined pattern on the barrier layer.

As shown in the structure of FIG. 12(B), after the barrier layer 80 is formed, a photoresist layer 90 having a predetermined pattern is formed on the barrier layer.

Specifically, a photoresist is coated on the barrier layer to form the photoresist layer 90, and the photoresist layer 90 covers the barrier layer 80. After forming a photoresist layer, an exposure machine combined with a mask can be used to perform local light treatment on the photoresist layer 90. The mask is provided with corresponding patterns. The mask is arranged between a light source and the photoresist layer 90. During the illumination process, the patterns on the mask block the light, so that part of the light from the light source irradiates the photoresist layer 90. The photoresist layer 90 after partial light treatment is placed into a developing solution for developing treatment. In the process of performing local light treatment on the photoresist layer through the mask, the chemical properties of the photoresist layer irradiated by the light change, so that the developer can remove part of the photoresist to form a photoresist with a predetermined pattern Layer 90.

Step B23: etching the barrier layer so that the barrier layer exposes the first flexible substrate.

The barrier layer 80 is etched by using a wet etching method. Specifically, a transparent conductive oxide etching solution or an indium tin oxide etching solution is used to etch the barrier layer. Since the photoresist layer 90 has a predetermined pattern, a part of the barrier layer 80 is exposed. The transparent conductive oxide etching solution or the indium tin oxide etching solution etches the exposed barrier layer 80 so that the barrier layer 80 exposes the first flexible substrate 10. The etched pattern of the barrier layer 80 is as shown in FIG. 12(C).

Step B24: Remove the photoresist layer with the predetermined patterns.

Specifically, the photoresist layer 90 above the barrier layer 80 is removed using a photoresist layer stripping solution, thereby obtaining the structure as shown in FIG. 12(D).

Step B25: etching the first flexible substrate to form a groove.

The first flexible substrate 10 may be etched by using a dry etching process. Specifically, the barrier layer 80 after the etching process has a predetermined pattern. The surface of the first flexible substrate 10 that is not covered with the barrier layer 80 is exposed. The first flexible substrate 10 is etched by oxygen (O₂), thereby forming the groove 11. The etched pattern of the first flexible substrate 10 is as shown in FIG. 12(E).

Step B26: removing the barrier layer.

After the groove 11 is formed on the first flexible substrate 10, the barrier layer 80 can be removed by a transparent conductive oxide etching solution or an indium tin oxide etching solution to obtain a structure as shown in FIG. 12(F).

Step B30: forming a first buffer layer on the first surface.

After the first flexible substrate is etched, the first buffer layer can be formed by a chemical vapor deposition method. The first buffer layer covers the groove. The material of the first buffer layer may be silicon oxide. Silicon oxide is a colorless transparent material, which is conducive to the transmission of light. The first buffer layer formed is a high-density silicon oxide film. High-density silicon oxide can effectively block water and oxygen, thereby reducing the influence of water and oxygen on the display panel, which is beneficial to prolong the service life of the display panel.

Step B40: forming a second flexible substrate on the first buffer layer.

The step of forming the second flexible substrate is the same as the step of forming the first flexible substrate and will not be repeated here.

In some embodiments, after the second buffer layer is formed, an opening is formed on the side of the second buffer layer away from the first flexible substrate. The grooves and the openings are arranged correspondingly.

It can be understood that the step of forming the opening is the same as the step of forming the groove and will not be repeated here.

Step B50: forming a second buffer layer on the second flexible substrate.

The steps of forming the second buffer layer are the same as the steps of forming the first buffer layer and will not be repeated here. The first buffer layer and the second buffer layer are both high-density silicon oxide films. The double-layer high-density silicon oxide film can further improve the performance of the display panel to isolate water and oxygen, thereby reducing the influence of water and oxygen on the display panel and is beneficial to increase the lifespan of the display panel.

In some embodiments, after the second buffer layer is formed, a driving circuit layer and a light emitting device layer may be formed on the second buffer layer, so that the display panel has a display function.

It is understandable that after the encapsulation layer is formed, a touch layer or other functional film layer may be formed on the surface of the display panel, so that the display panel has a touch function or other functions.

The embodiment of the present application provides a fabrication method of a display panel, and the fabricated display panel adopts a structure of a double-layer flexible substrate combined with a double-layer buffer layer. The double-layer buffer layer is a dense film layer, which can improve the performance of the display panel to isolate water and oxygen, thereby reducing the influence of water and oxygen on the display panel and is beneficial to increase the lifespan of the display panel. At the same time, the fabrication method of the display panel provided by the present application is provided with grooves in the under-screen imaging area of the first flexible substrate of the display panel, which reduces the thickness of the flexible substrate in the under-screen imaging area and improves the under-screen of the display panel. The light transmittance of the camera area improves the imaging effect of the under-screen camera of the display panel.

The above is a detailed introduction to a mobile terminal provided by an embodiment of the present application. Specific examples are used in this article to illustrate the principles and implementation of the present application. Its core idea, at the same time, for those skilled in the art, according to the idea of this application, there will be changes in the specific implementation and scope of application. In summary, the content of the present specification should not be construed as a limitation to this application.

What is claimed is:

1. A display panel, comprising:
an under-screen camera area and a non-under-screen camera area that are adjacently arranged, wherein the display panel comprises:
a first flexible substrate, comprising a first surface and a second surface opposite to each other, wherein the first surface is provided with a groove and the groove is located in the under-camera area;
a first buffer layer located on the first surface;
a second flexible substrate located on a side of the first buffer layer away from the first flexible substrate; and
a second buffer layer located on a side of the second flexible substrate away from the first buffer layer.

2. The display panel of claim 1, wherein the second flexible substrate comprises an opening, the opening is located on a side of the second flexible substrate away from the first buffer layer, and the groove and the opening are arranged correspondingly.

3. The display panel of claim 2, wherein the opening penetrates the second flexible substrate, and the second buffer layer is connected to the first buffer layer through the opening.

4. The display panel of claim 2, wherein a cross-sectional area of the opening along a thickness direction perpendicular to the second flexible substrate is greater than or equals to a cross-sectional area of the groove along a thickness direction perpendicular to the first flexible substrate.

5. The display panel of claim 1, wherein the first flexible substrate comprises a plurality of the grooves, and the plurality of grooves are arranged in the under-screen imaging area.

6. The display panel of claim 5, wherein the plurality of grooves are annular grooves, and the plurality of the grooves are concentrically arranged.

7. The display panel according to claim 5, wherein a cross-sectional width of one of the grooves along the thickness direction of the first flexible substrate is between 10 micrometers and 20 micrometers.

8. The display panel of claim 5, wherein a distance between the adjacent grooves is between micrometers and 20 micrometers.

9. The display panel of claim 1, wherein the display panel further comprises a light emitting device layer, the light emitting device layer is located on a side of the second buffer layer away from the second flexible substrate, the light emitting device layer comprises a plurality of pixels, and the plurality of pixels are distributed in the under-screen camera area and the non-under-screen camera area, wherein:
a pixel density of the under-screen camera area is smaller than a pixel density of the non-under-screen camera area.

10. The display panel of claim 9, wherein the display panel further comprises a driving circuit layer located between the light emitting device layer and the second buffer layer, the driving circuit layer is configured to control light emission of the pixel, the driving circuit layer comprises a plurality of thin film transistors, and the plurality of thin film transistors respectively correspond to the pixels, wherein:
the plurality of thin film transistors are connected to the plurality of pixels of the under-screen imaging area are located in the non-under-screen imaging area.

11. The display panel of claim 10, wherein the signal traces in the driving circuit layer are transparent wires.

12. The display panel of claim 1, wherein the display panel further comprises a blocking member, the blocking member is located on a side of the second buffer layer away from the second flexible substrate, and the blocking member is located between the under-screen camera area and the non-under-screen camera area.

13. The display panel of claim 1, wherein a material of the first flexible substrate and the second flexible substrate is a transparent polyimide material or a transparent polyester material.

14. The display panel of claim 1, wherein a material of the first buffer layer and the second buffer layer is silicon oxide.

15. The display panel of claim 1, wherein a thickness of the first flexible substrate and the second flexible substrate is between 6 micrometers and 12 micrometers.

16. The display panel of claim 1, wherein a thickness of the first buffer layer and the second buffer layer is between 100 nanometers and 600 nanometers.

17. The display panel of claim 1, wherein the depth of the groove is between 1 micrometer and 3 micrometers.

18. The display panel of claim 2, wherein a depth of the opening is between 1 micrometer and 6 micrometers.

19. A fabrication method of a display panel, comprising:
providing a first flexible substrate, wherein the first flexible substrate comprises a first surface and a second surface that are opposed to each other;
forming a groove on the first surface, wherein the groove is located in an under-screen camera area of the display panel;
forming a first buffer layer on the first surface;
forming a second flexible substrate on the first buffer layer; and
forming a second buffer layer on the second flexible substrate.

20. The fabrication method of the display panel according to claim 19, wherein the step of forming a groove on the first surface comprises:
forming a barrier layer on the first flexible substrate;
forming a photoresist layer with a predetermined pattern on the barrier layer;
etching the barrier layer so that the barrier layer exposes the first flexible substrate;
removing the photoresist layer with the predetermined pattern;
etching the first flexible substrate to form the groove; and
removing the barrier layer.
